(19) United States
(12) Patent Application Publication
(10) Pub. No.: US 2005/0253268 A1
(43) Pub. Date: Nov. 17, 2005

(54) Method and structure for improving adhesion between intermetal dielectric layer and cap layer

(76) Inventors: Shao-Ta Hsu, Tainan City (TW); Kuo-Hsien Cheng, Tainan City (TW); Shwang-Ming Jeng, Hsin-Chu (TW); Hung-Tsai Liu, Taichung (TW); Wei-Cheng Chu, Tainan City (TW); Yu-Ku Lin, Hsin Chu (TW); Ying-Lang Wang, Hsin-Chu (TW)

Correspondence Address: SLATER & MATSIL, L.L.P., 17950 PRESTON ROAD, SUITE 1000, DALLAS, TX, 75252, US

(21) Appl. No.: 10/967,009

(22) Filed: Oct. 15, 2004

Related U.S. Application Data
(60) Provisional application No. 60/564,365, filed on Apr. 22, 2004.

(51) Int. Cl. H01L 23/48

(52) U.S. Cl. 257/758

(57) ABSTRACT

A semiconductor interconnect structure including a semiconductor substrate, a semiconductor active device formed in the substrate, a layer of low-k dielectric material, a first patterned conducting layer, a second patterned conducting layer, and a cap layer formed thereon. The low-k material layer is formed over the semiconductor device. The first conducting line is formed in the low-k material layer and connected to the semiconductor active device. The second conducting line is formed in the low-k material layer but not electrically connected to the semiconductor active device. The cap layer is formed over the low-k material layer, the first and second conducting lines. The cap layer includes silicon and carbon. Since the adhesion strength between the cap layer and the patterned conducting layer is greater than the adhesion strength between the cap layer and the low-k material layer, the addition of second patterned conducting layer would eliminate the overall possibility of delamination between the surface where cap layer is in contact with the low-k material and the first and the second patterned conducting layers.

### TECHNICAL FIELD

The present invention generally relates to a semiconductor interconnect structure and methods of making the same.

### BACKGROUND

Many semiconductor devices incorporate low-k materials in the intermetal dielectric (IMD) layers to reduce capacitance between metal lines. Generally, low-k dielectric materials are materials having a dielectric constant less than that of silicon oxide, or preferably less than about 4.0. Typically, low-k materials are porous, soft, and weak relative to silicon oxide, and often have high thermal expansion rates and low thermal conductivity relative to neighboring structures and layers. These properties may lead to poor adhesion between the low-k material and its neighboring structures or layers. Therefore, a cap layer is often provided between IMD layers to eliminate the delamination issues.

FIG. 1 is a cross-section view for part of an example semiconductor interconnect structure 20 of the prior art at an intermediate stage after forming a cap layer 24 over an IMD layer 28. The IMD layer 28 includes a low-k dielectric material layer 30 with patterned copper conducting layer 31 formed therein. The material of the cap layer 24 includes silicon and carbon. The IMD layer 28 is formed over a semiconductor active device 42. The semiconductor active device 42 is formed on or in a semiconductor substrate 40. In this example, the patterned conducting layer 31 is electrically connected to the active device 42 via another conducting path 43.

As commonly known, most materials volumetrically expand when heated, but expand to different extent, even under a same temperature increment. By this phenomenon, we can define the thermal expansion coefficient and every material has its own coefficient. If the thermal expansion coefficient of one material differs from that of another material adheres to it, the adhesion strength between these two materials would be weakened after certain thermal cycles. This is because they will expand to different extents when heated, and shrink to different extents when cooled. In the prior art structure shown in FIG. 1, the portions of the patterned conducting layer 31 are irregularly spaced, and there are regions 50 between 31. Since the thermal expansion coefficients of low-k material 30 and the cap layer 24 differ greatly, the cap layer 24 will tend to delaminate from the IMD layer 28 (made of low-k material 30) when external stress is exerted on the cap layer 24. Typical external stress comes from thermal cycles in fabrication process, or from a subsequent chemical-mechanical polishing (CMP) process due to heat generated by friction and exerted on the top surface of the semiconductor interconnect structure 20. Hence, a need exists for a way to prevent or significantly reduce delamination between the cap layer 24 and the IMD layer 28 in the semiconductor interconnect structure 20.

### SUMMARY OF THE INVENTION

The problems and needs outlined above may be addressed by embodiments of the present invention. In accordance with one aspect of the present invention, a semiconductor interconnect structure is provided, which includes a semiconductor substrate, a semiconductor active device, a layer of low-k dielectric material, a first patterned conducting layer, a second patterned conducting layer, and a cap layer. The semiconductor device is formed on and/or in the semiconductor substrate. The layer of low-k dielectric material is formed over the semiconductor device. The first patterned conducting layer is formed in the low-k material layer and electrically connected to the semiconductor active device. Then, the second patterned conducting layer is formed in the low-k material layer, which performs as a dummy layer that is not electrically connected to any semiconductor active device. The cap layer is formed over the low-k material layer and on the first and second patterned conducting layers. In some cases, the cap layer preferably comprises silicon and carbon, and the atomic fraction of carbon is roughly more than 30%. According to observation, the adhesion strength between the cap layer and the first and the second patterned conducting layers is greater than that between the cap layer and the low-k material layer. Thus, even though the second patterned conducting layer is not electrically connected to the semiconductor active device and provide no function for electrical connection, the existence of the second conducting line may reduce the excessive stress, and eliminate the delamination at the surface between the cap layer and the low-k layer.

Furthermore, it is also found that even though the cap layer is not in physical contact with the surface on top of the low-k material layer and the first patterned conducting layer, the addition of the second patterned conducting layer may still eliminate the possibility of delamination. In this case, there may be a barrier layer (not shown in FIG. 2) formed between the cap layer and the low-k dielectric layer.

In accordance with another aspect of the present invention, a semiconductor interconnect structure is provided, which includes a semiconductor substrate, a semiconductor active device, an intermetal dielectric layer, and a cap layer. The semiconductor device is formed on and/or in the semiconductor substrate. The intermetal dielectric layer, formed over the semiconductor active device, includes a layer of low-k dielectric material. A first patterned conducting layer, electrically connected to the semiconductor active device, is formed in the low-k material layer. The first patterned conducting layer preferably includes copper. A second patterned conducting layer, which is not electrically connected to the any semiconductor active device, is also formed in the low-k material layer. The second patterned conducting layer also preferably includes copper. The cap layer, preferably comprising silicon and carbon, is formed over the intermetal dielectric layer. Since the adhesion strength between the cap layer and the second patterned conducting layer is greater than that between the cap layer and the low-k material layer, the addition of the second patterned conducting layer may reduce the excessive stress and eliminate the possibility of delamination at the surface between the cap layer and the intermetal dielectric layer.

Again, it is also found that, even though the cap layer is not in physical contact with the surface on top of the intermetal dielectric layer and the first patterned conducting layer, the addition of the second patterned conducting layer may still eliminate the possibility of delamination. In this case, there may be a barrier layer (not shown) formed between the cap layer and the low-k dielectric layer.

In accordance with yet another aspect of the present invention, a method of improving adhesion between a cap layer and an intermetal dielectric layer, in a semiconductor interconnect structure, is provided. This method includes the following steps, not necessary in the order or sequence, described in this paragraph. First, a low-k dielectric material layer, acting as an intermetal dielectric, is formed over a semiconductor active device in a semiconductor substrate. Then a first patterned conducting layer is formed electrically connected to the semiconductor active device in the low-k material layer. A second patterned conducting layer, acting as a dummy layer and not electrically connected to any semiconductor active device, is formed in the low-k material layer. Finally, the cap layer is formed over the intermetal dielectric layer. The cap layer preferably includes silicon and carbon. Due to the addition of the second conducting layer, the overall adhesion strength at the surface between the cap layer and the low-k material layer is now greater than that of the condition when only the first patterned conducting layer exists in the low-k material layer.

The foregoing has outlined rather broadly features of the present invention in order that the detailed description of the invention that follows may be better understood. Additional features and advantages of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The following is a brief description of the drawings, which illustrate exemplary embodiments of the present invention and in which:

FIG. 1 is a cross-section view for part of an example semiconductor interconnect structure of the prior art at an intermediate stage after forming a cap layer on an IMD layer;

FIG. 2 is a cross-section view for part of a semiconductor interconnect structure for a first embodiment of the present invention;

FIG. 3 is a cross-section view for part of an example semiconductor interconnect structure of the prior art with a dual damascene structure for the conducting line of the IMD layer;

FIG. 4 is a cross-section view for part of a semiconductor interconnect structure of a second embodiment of the present invention;

FIG. 5 is a cross-section view for part of a semiconductor interconnect structure of a third embodiment of the present invention;

FIG. 6 is a top view of a semiconductor chip depicting semiconductor interconnect structures of the present invention according to embodiments mentioned above; and

FIG. 7 is a top view of some examples of the patterned conducting layers according to an embodiment of the present invention.

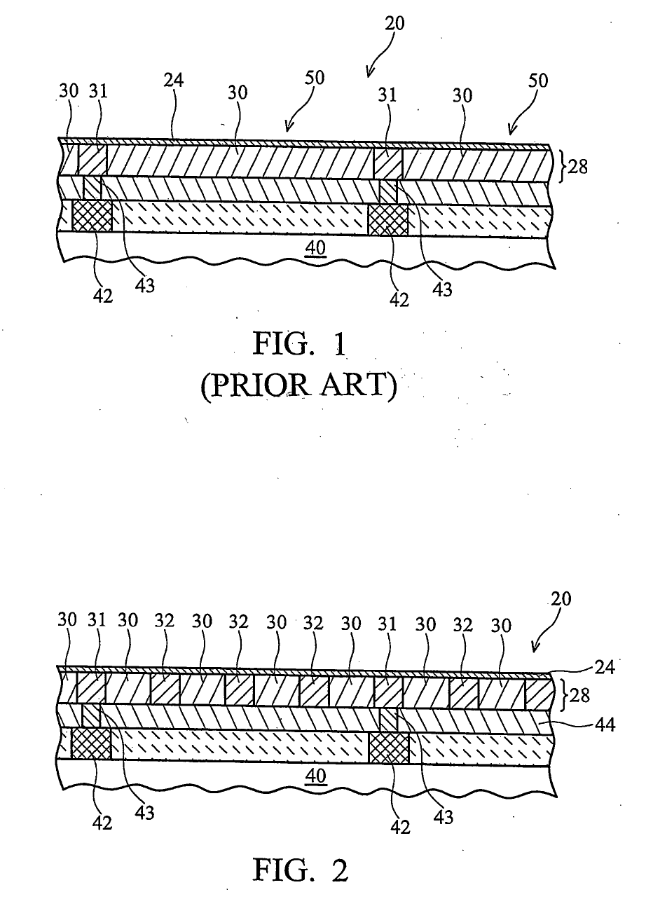

### DETAILED DESCRIPTION OF ILLUSTRATIVE EMBODIMENTS

Referring now to the drawings, wherein like reference numbers are used herein to designate like or similar elements throughout the various views, illustrative embodiments of the present invention are shown and described. The figures are not necessarily drawn to scale, and in some instances, the drawings have been exaggerated and/or simplified in places for illustrative purposes only. One of ordinary skill in the art will appreciate the many possible applications and variations of the present invention based on the following illustrative embodiments of the present invention.

Generally, an embodiment of the present invention provides a scheme and method of improving adhesion between an IMD (inter-metal dielectric) layer and a cap layer in contact therewith in a semiconductor interconnect structure. FIG. 2 is a cross-section view for part of a semiconductor interconnect structure 20 for a first embodiment of the present invention. The interconnect structure 20 of FIG. 2 is shown at an intermediate stage after forming a cap layer 24 on an IMD layer 28. The IMD layer 28 of the first embodiment includes a low-k dielectric material layer 30 with a first patterned conducting layer 31 (drawn as a set of conducting lines due to cross section view) formed therein. The material of the cap layer 24 preferably includes silicon and carbon. The IMD layer 28 is formed over semiconductor active devices 42. The semiconductor active devices 42 are formed on and/or in a semiconductor substrate 40. In the first embodiment, the semiconductor active devices 42 can be transistors having gate electrodes. The semiconductor active devices 42, which are electrically connected to other similar devices to provide electrical function, may vary for other embodiments, including (but no limited to): gate electrodes, transistors, capacitors, resistors, conductors, or combinations, for example. The wires of the first patterned conducting layer 31 are electrically connected to the semiconductor devices 42 via conducting paths, such as contact plugs 43, as shown in FIG. 2 for example. A second patterned conducting layer 32 (again, drawn as a set of conducting lines by cross section view) are added, which are not electrically connected to the semiconductor active devices 42, at least not connected to those connected to by the first patterned conducting layer 31, as a dummy conducting layer. The dummy conducting layer 32 may be electrically connected to a ground (not shown) to prevent stray electric fields from developing therein. As described in more detail below, adding the dummy conducting layer 32 may eliminate the possibility of delamination at the surface between the cap layer 24 and the IMD layer 28.

The low-k dielectric material layer 30 may include any suitable low-k dielectric material, including (but not limited to): Black Diamond™ (available by Applied Materials, Inc.), fluorinated silicate glass or fluorinated silicon oxide glass (FSG), SiOₓC_{y}, Spin-On-Glass, Spin-On-Polymers, SILK™ available from Dow Chemical, FLARE™ available from Honeywell, LKD (low k dielectric) from JSR Micro, Inc., hydrogenated oxidized silicon carbon material (SiCOH), amorphous hydrogenated silicon (a-Si:H), SiOₓN_{y}, SiC, SiCO, SiCH, compounds thereof, composites thereof, and combinations thereof, for example. The cap layer 24 may be made from any of a variety of suitable materials that include silicon and carbon, including (but not limited to): SiC (sometimes sold under the trademark BLOK™ by Applied Materials, Inc.), SiCN (sometimes sold under the trademark n-BLOK™ by Applied Materials, Inc.), a silicon-carbon compound having at least 30% carbon, carbon-doped silicon nitride (SiₓN_{y}Cₓ), composites thereof, and combinations thereof, for example. The patterned conductive layers 31 and 32 may be formed from any of a variety of suitable conducting materials, including (but not limited to): metal nitride, metal alloy, copper, copper alloy, aluminum, aluminum alloy, gold, gold alloy, composites thereof, and combinations thereof, for example. In a preferred embodiment, the second patterned conducting layer 32 is formed using the same materials and steps used to form the first conducting layer 31. In other embodiments, however, the patterned conducting layer 32 may be formed from a different material than the first patterned conducting layer 31. The contact plugs 43 are preferably formed from copper, but may be made from other materials. Although contact plugs 43 formed of a material different from that of the conducting lines 31 are typically used for making connections to the semiconductor active devices 42, it is contemplated that the same material of the conducting lines 31 may be used for making a connection to the semiconductor active devices 42 (e.g., single damascene structure, dual damascene structure).

Not that during the fabrication of the semiconductor interconnect structure 20, there may be a need to slow down or even stop the etching at the interface of the IMD layer 28 and the dielectric layer 44, prior to forming patterned conducting layers 31 and 32 in IMD layer 28. Thus, there can be another dielectric layer (not shown in FIG. 2) interposed between IMD layer 28 and the dielectric layer 44, which has higher resistance than IMD layer 28, to provide better capability to hinder etching. Some dielectric layer with material like SiN, SiC, SiON, SiOC or combinations thereof may be a good choice for this dielectric layer, for example.

In a preferred embodiment of the present invention, the low-k dielectric material layer 30 is made from Black Diamond™ from Applied Materials, Inc., the patterned conducting layers 31 and 32 are formed from copper or a copper alloy (preferably with a barrier layer also, not shown), and the cap layer 24 is preferably SiC (e.g., BLOk™ from Applied Materials, Inc.). It has been found through testing that the adhesion strength between the Black Diamond material (low-k layer 30) of the IMD layer 28 and the BLOK™ material (SiC cap layer 24) may be about five times weaker than the adhesion strength between copper conducting layers 31 and 32 and BLOk™ material (SiC cap layer 24). For example, in a four-point bending test on a prior art structure (without dummy conducting layer 32) having BLOk™ material for the cap layer 24, copper for the first conducting layer 31, and Black Diamond™ material for the low-k material layer 30, the adhesion strength at the Cu/BLOk interface was measured to be about 24.80 J/m² and the adhesion strength at the Black Diamond/BLOk interface was measured to be about only 5.01 J/m². Thus, increasing the Cu/SiC interface area by adding the dummy patterned conducting layer 32 and thus reducing the low-k IMD/SiC interface area in accordance with an embodiment of the present invention will greatly increase overall interface strength between the low-k containing IMD layer 28 and the SiC cap layer 24.

In FIG. 2, the width and number of segments of conducting layer 32 (observed by the cross section view along its lateral) is also a key to the performance of improving adhesion between cap layer 24 and IMD layer 28. First, the conducting layer 32 and the conducting layer 31 are usually fabricated at the same process steps, so in a preferred embodiment the width of segments of conducting layer 32 would be roughly same as the width of segments conducting layer 31, or within around 20% variation. Second, even though the addition of conducting layer 32, meaning the increment of area where cap layer contacts the metal, will increase the adhesion strength, too much addition or too large area of conducting layer 32 will cause other issues. This is because when too much metal area is exposed in the IMD layer 28, the erosion in the metal area, due to CMP (Chemical-Mechanical-Polishing) exertion on the surface of IMD layer 28, becomes severe and results in weak adhesion to cap layer 24 deposits afterwards.

In this invention, the proper portion of dummy conducting layer 32 in the IMD layer 28 is also evaluated to balance both concerns mentioned above: minimum erosion possibility and maximum adhesion enhancement. It is found that, between two segments of patterned conducting layer 31, if the area ratio, defined by the sum of the areas where the cap layer contacts the dummy conducting layer 32 to the total area between two segments of patterned conducting layer 31, is in the range of about 20% to 80%, the adhesion increment would become noticeable and erosion possibility be still tolerable. To be specific, roughly 50% area ratio is most preferable by its performance.

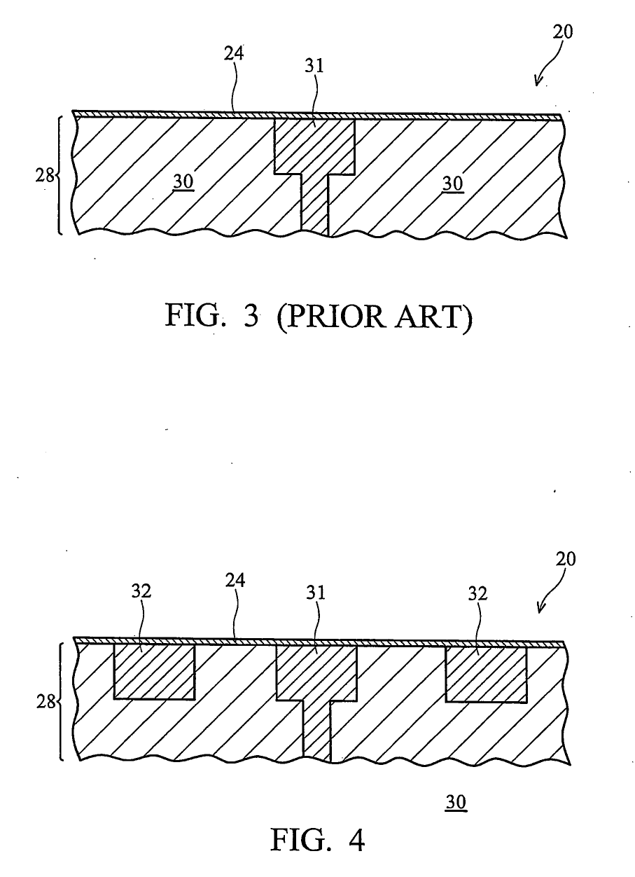

FIG. 3 is a cross-section view for part of a semiconductor interconnect structure 20 of the prior art with a dual damascene structure for the patterned conducting layer 31 shown. FIG. 4 is a cross-section view for part of a semiconductor interconnect structure 20 of a second embodiment of the present invention. The second embodiment is essentially the same as the first embodiment (see FIG. 2), except that at least some of the first patterned conducting layer 31 is formed as a dual damascene structure (see FIG. 4). One or more of the patterned dummy conducting layer 32 may have a dual damascene structure in other embodiments (not shown), as long as not electrically connected to the semiconductor active devices 42.

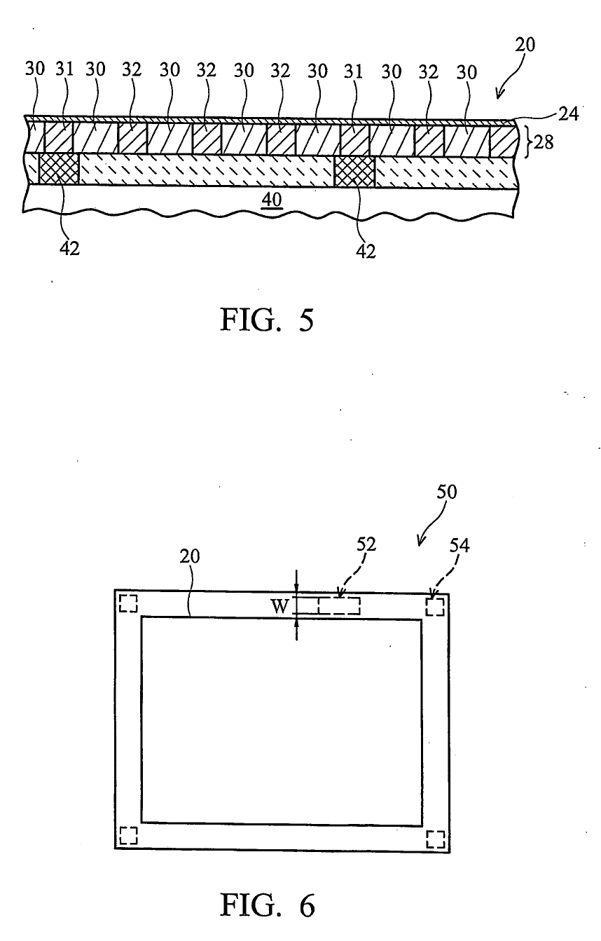

FIG. 5 is a cross-section view for part of an semiconductor interconnect structure 20 of a third embodiment of the present invention having patterned dummy conductive layer 32 to increase adhesion strength between the IMD layer 28 and the cap layer 24. In the third embodiment, the first patterned conducting layer 31 is electrically connected to the semiconductor active devices 42 directly (e.g., using copper).

The structure comprising a patterned dummy conducting layer may enhance the adhesion strength between IMD layer and cap layer, and is especially advantageous for two conditions: one is when applied at periphery region of semiconductor chip, the other is applied for upper levels of semiconductor interconnects. First, the periphery areas of semiconductor chip typically experience the maximum stress variation during fabrication of semiconductor chips, thus a effective design for strengthening the inter-layers adhesion may be desired or needed.

Referring to FIG. 6, the periphery 52 of the semiconductor chip 50 is defined as a narrow belt or zone having a width W of about, or slightly greater than, 10% of the width of the semiconductor chip 50. Given that the semiconductor chip 50 may be rectangular and not square, the periphery's width W may be taken as 10% of one or the other of the dimensions of the semiconductor chip, or as 10% of the average of these dimensions. Furthermore, the corners 54 on the semiconductor chip 50 are where the invention may take effect the most. It's because the corners 54 usually experience more stress than other regions of periphery area 52 while dicing or cutting during semiconductor chip fabrication.

As indicated above, the belt or zone 52 may comprise or include numerous semiconductor interconnect structure 20. Each semiconductor interconnect structure 20 is electrically associated with a one or more of the other devices on the semiconductor chip 50 functioning together as a specific circuit or block, such as a memory, processor, counter, voltage source, or the like. The semiconductor interconnect structure 20 located on or within the periphery 52 normally experience very high stress due to the accumulation of stresses arising from the fabrication of multiple devices in and on the semiconductor chip 50. With dummy patterned conducting layer 32 incorporated within the interconnect structure 20, the adhesion between IMD layers and cap layers is increased and the issues of delamination is be eliminated.

The structure comprising dummy conducting layer to enhance the adhesion strength between IMD layer and cap layer is also effective when applied for upper levels of semiconductor interconnects. Semiconductor interconnect structures are usually fabricated with several levels based on their design. During fabrication, the upper levels often experience more stress than that of the lower levels. Thus, the invention presented is more preferably used for upper interconnection levels. For example, the upmost two levels of interconnection (i.e. the top level and the one underneath it) of a semiconductor chip may be and advantageous place (or even a best place) to apply this invention.

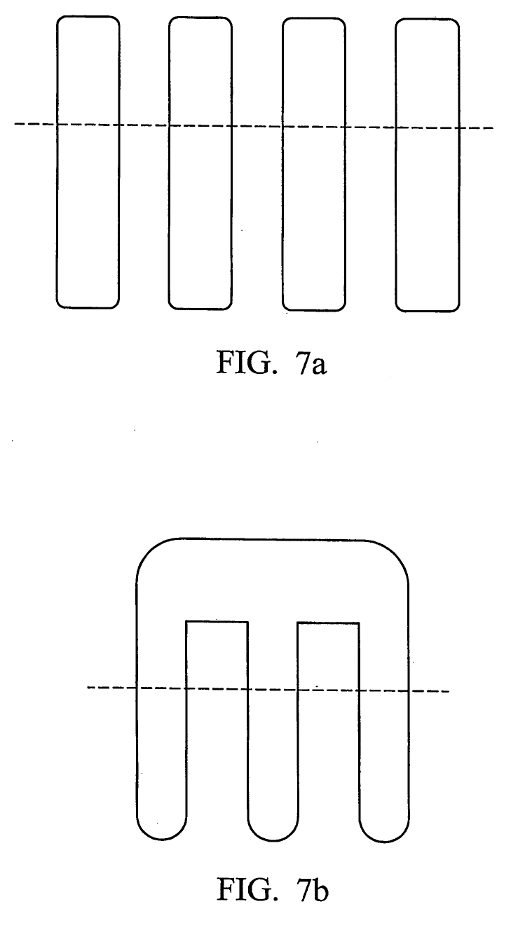

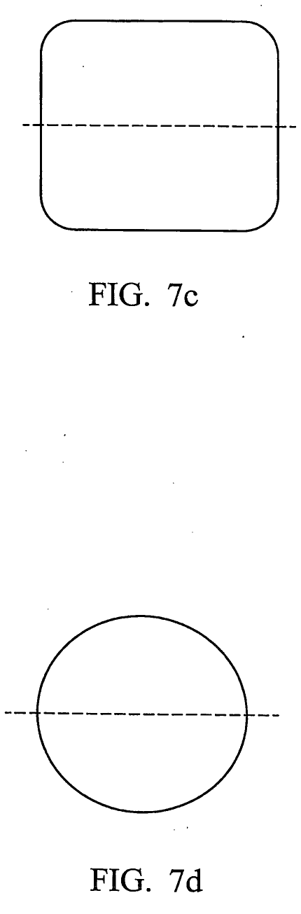

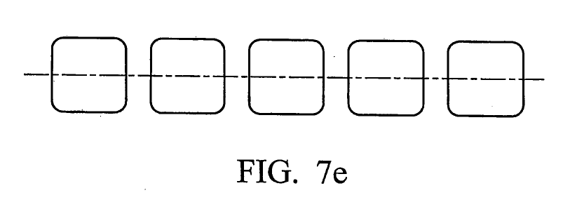

It should be noticed that, even though the patterned conducting layers 31 and 32 are drawn as separate lines by cross section view in FIG. 2, FIG. 4, and FIG. 5, they are actually conducting layers patterned as having one or more segments of line shape or rectangular shape. FIGS. 7a-7e illustrate some example shapes of patterned conducting layer by plane view. Also, a dashed line in each of FIGS. 7a-7e shows where the cross section views of FIG. 2, FIG. 4, and FIG. 5 are taken. Usually the shape of FIG. 7a with several single lines, or of FIG. 7b with several segments of line shape with at least two segments are physically connected, are mostly applied. In some condition, the conducting layer may be patterned as substantially a rectangular shape or furthermore the rounded shape, as FIG. 7c and FIG. 7d illustrate respectively, are also utilized. Sometimes the conducting layer may even be patterned as an enlarged dashed line or dotted line as in FIG. 7e, preferably with all segments fabricated at the same time. All the examples mentioned above are just examples showing some variety of the patterned conducting layer in this invention, and surely not a limitation to this invention.

Although embodiments of the present invention and at least some of its advantages have been described in detail, it should be understood that various changes, substitutions, and alterations can be made herein without departing from the spirit and scope of the invention as defined by the appended claims. Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor interconnect structure comprising:
a semiconductor substrate;
a semiconductor active device formed in the semiconductor substrate;
a layer of low-k dielectric material formed over the semiconductor device;
a first patterned conducting layer formed in the low-k material layer, the first patterned conducting layer being electrically connected to the semiconductor active device;
a second patterned conducting layer formed in the low-k material layer, the second patterned conducting layer is not electrically connected to any semiconductor active devices; and
a cap layer formed over the low-k material layer and on the first and second patterned conducting layers.

2. The semiconductor interconnect structure of claim 1, wherein at least one of the first and second patterned conducting layers comprises copper.

3. The semiconductor interconnect structure of claim 1, wherein the second patterned conducting layer comprises at least one segment of substantially line shape, rectangular shape, or rounded shape.

4. The semiconductor interconnect structure of claim 1, wherein the second patterned conducting layer is a patterned layer with dotted line shape, or dashed line shape.

5. The semiconductor interconnect structure of claim 1, wherein the cap layer comprises silicon and carbon.

6. The semiconductor interconnect structure of claim 1, wherein the cap layer has a thickness less than about 600 angstroms.

7. The semiconductor interconnect structure of claim 5, wherein the cap layer comprises at least 30% carbon.

8. The semiconductor interconnect structure of claim 1, wherein the layer of low-k dielectric material has a dielectric constant less than that of silicon oxide.

9. The semiconductor interconnect structure of claim 1, wherein the low-k material layer comprises silicon and carbon.

10. The semiconductor interconnect structure of claim 1, wherein the low-k material layer comprises fluorine-doped silicon glass (FSG).

11. The semiconductor interconnect structure of claim 9, wherein the low-k material layer comprises Black Diamond.

12. The semiconductor interconnect structure of claim 1, wherein the semiconductor interconnect structure is located on a peripheral region surrounding a semiconductor chip in which the semiconductor interconnect structure is formed.

13. The semiconductor interconnect structure of claim 12, wherein the width of the peripheral region is about 10% of the width of the semiconductor chip.

14. A semiconductor interconnect structure comprising:
a semiconductor substrate;
a semiconductor active device formed in the semiconductor substrate;
a dielectric layer formed over the semiconductor device, the dielectric layer comprising a layer of low-k dielectric material;
a first patterned conducting layer formed in the dielectric layer, the first patterned conducting layer being electrically connected to the semiconductor active device, and the first patterned conducting layer comprising copper;
a second patterned conducting layer formed in the dielectric layer, the second patterned conducting layer is not electrically connected to any semiconductor active devices, and the second patterned conducting layer comprising copper; and
a cap layer formed over the dielectric layer, the first patterned conducting layer, and the second patterned conducting layer.

15. The semiconductor interconnect structure of claim 14, wherein the cap layer comprises silicon and carbon.

16. The semiconductor interconnect structure of claim 14, wherein the low-k material layer comprises silicon and carbon.

17. A method to eliminate delamination between a cap layer and an dielectric layer in a semiconductor interconnect structure, comprising:
forming a low-k dielectric material layer for the dielectric layer over a semiconductor active device, the semiconductor device being formed in a semiconductor substrate;
forming a first patterned conducting layer in the low-k material layer, the first patterned conducting layer being electrically connected to the semiconductor device;
forming a second patterned conducting layer in the low-k material layer, the second patterned conducting layer is not electrically connected to the any semiconductor active devices; and
forming the cap layer over the intermetal dielectric layer, the first patterned conducting layer and the second patterned conducting layer.

18. The method of claim 17, wherein the first and second patterned conducting layer comprises copper.

19. The method of claim 17, wherein the cap layer comprises silicon and carbon.

20. The method of claim 17, wherein the cap layer has a thickness less than about 600 angstroms.

21. The method of claim 17, wherein the cap layer has a dielectric constant substantially less than that of silicon oxide.

22. The method of claim 17, wherein the low-k material layer comprises silicon and carbon.

23. The method of claim 17, wherein the low-k material layer comprises fluorine-doped silicon glass (FSG).

24. The method of claim 22, wherein the low-k material layer comprises Black Diamond.

25. A method of improving adhesion between a cap layer and a dielectric layer in a semiconductor interconnect structure, comprising:
forming a low-k dielectric material layer for the dielectric layer over a semiconductor active device, the semiconductor active device being formed in a semiconductor substrate;
forming a first patterned conducting layer in the low-k material layer, the first patterned conducting layer being electrically connected to the semiconductor active device;
forming a second patterned conducting layer in the low-k material layer, the second patterned conducting layer being a dummy layer that is not electrically connected to the first patterned conducting layer; and
forming the cap layer on the dielectric layer, wherein a first adhesion strength between the cap layer and the second patterned conducting layer is greater than a second adhesion strength between the cap layer and the low-k material layer.

26. The method of claim 25, wherein the cap layer comprises silicon and carbon, and wherein the second patterned conducting line comprises copper.
